(19) United States
(12) Patent Application Publication
(10) Pub. No.: US 2015/0086729 A1
(43) Pub. Date: Mar. 26, 2015

(54) METHOD FOR PRODUCING A SUBSTRATE WITH STACKED DEPOSITION LAYERS

(71) Applicant: SoLayTec B.V., Eindhoven (NL)

(72) Inventors: Roger Mathias Wilhelm Görtzen, Eindhoven (NL); Sebastiaan Antonius Fransiskus Dielissen, Eindhoven (NL); Joseph Adrianus Maria De Swart, Eindhoven (NL); Adrianus Johannes Petrus Maria Vermeer, Eindhoven (NL)

(21) Appl. No.: 14/390,620

(22) PCT Filed: Apr. 2, 2013
(86) PCT No.: PCT/NL2013/050241

§ 371 Date: Oct. 3, 2014

(30) Foreign Application Priority Data
Apr. 3, 2012 (NL) 2008592

(51) Int. Cl. C23C 16/455; C23C 16/40; C23C 16/34

(52) U.S. Cl. CPC C23C 16/45529; C23C 16/45536; C23C 16/345; C23C 16/403
USPC 427/576; 427/569; 427/586; 118/723 R

(57) ABSTRACT

A stacked substrate is produced using an apparatus including an injector head device. Production includes the steps of providing an injector head device comprising a gas bearing pressure arrangement and injecting bearing gas against opposite substrate surfaces, to balance the substrate without support in a conveying plane in the injector head device. The following steps are performed iteratively: contacting opposite substrate surfaces with a first precursor gas; and with a second precursor gas, first and second precursor gases supplied in first and second deposition spaces are arranged opposite and facing respective sides of the substrate; establishing relative motion between the deposition space and the substrate in the conveying plane; and providing at least one of a reactant gas, plasma, laser-generated radiation, and/or ultraviolet radiation, in any or both reactant spaces for reacting any of the first and second precursor gas after deposition on at least part of the substrate surface.

### FIELD OF THE INVENTION

The invention relates to a method for producing substrate with stacked deposition layers, in particular a photocell, and an apparatus therefore. The invention further relates to a method for atomic layer deposition on a surface of a substrate.

### BACKGROUND

The use of stacked deposition layers can be highly beneficial for surface passivation of c-Si solar cells. A recent publication shows for example the use of a stacked layer of SiO₂—Al₂O₃. A low temperature SiO₂ deposition process is desired to prevent the degradation of doped c-Si, however until now that low temperature deposited SiO₂ is of insufficient quality.

Atomic layer deposition is a method for the deposition of ultrathin films for a variety of different target materials. Atomic layer deposition differs from for example chemical vapour deposition in that with atomic layer deposition the different precursor gasses used are dosed alternatively or spatially separated. During the first process step or so called half-cycle a precursor gas is dosed which reacts with the substrate surface in a self-limited way resulting in the deposition of the first target material (i.e. aluminium). During the second half cycle, a second precursor gas is dosed which reacts with the newly formed surface in a self-limiting way depositing the second target material (i.e. oxygen). One full atomic layer deposition cycle results in the deposition of one (sub)monolayer of the target material (i.e. aluminium oxide). Due to the self-limiting growth behaviour of each ALD half cycle, the advantage of an ultimate control of the target layer thickness can be achieved.

WO2011014070 discloses an apparatus for deposition of atomic layers. The apparatus discloses an air bearing effect so that a substrate hovers above an injector head. A challenge exists in producing multi stacked deposition layers of photocells which have a variable stack composition and thickness.

### SUMMARY

Accordingly, it is an object, according to an aspect of the invention to provide a method for producing a substrate with stacked deposition layers. According to an aspect of the present invention, the substrate is produced by a method comprising the steps of:

a) providing an injector head device comprising a gas bearing pressure arrangement;

b) injecting bearing gas from the gas bearing pressure arrangement against opposite substrate surfaces, to balance the substrate supportless in a conveying plane in the injector head device;

and iteratively performing the steps of

c) contacting opposite substrate surfaces with a first precursor gas from a first precursor supply; and with a second precursor gas from a second precursor supply respectively, first and second precursor gases supplied in first and second deposition spaces arranged opposite and facing respective sides of the substrate;

d) establishing relative motion between the deposition space and the substrate in the conveying plane, in order to convey the substrate to reactant spaces arranged in the injector head device opposite and facing respective sides of the substrate; and

e) providing at least one of a reactant gas, plasma, laser-generated radiation, and/or ultraviolet radiation, in any or both reactant spaces for reacting any of the first and second precursor gas after deposition on at least part of the substrate surface in order to obtain an atomic layer on each of opposite sides of the substrate surface;

f) wherein first and second precursor gases are at least in one of the iterations supplied simultaneously on opposite sides of the substrate.

### BRIEF DESCRIPTION OF THE DRAWINGS

The invention will now be described, in a non-limiting way, with reference to the accompanying drawings, in which:

FIG. 1 shows a first embodiment of a photocell;

FIG. 2 shows a second embodiment of a photocell;

FIG. 3 shows a schematic side view of an embodiment according to the invention

FIG. 4 shows a schematic plan view of another embodiment

FIG. 5 shows a schematic side view of another embodiment.

Unless stated otherwise, the same reference numbers refer to like components throughout the drawings.

### DETAILED DESCRIPTION

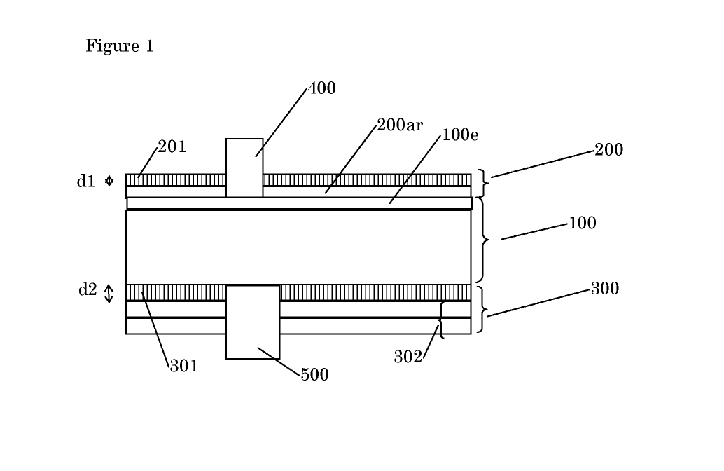

FIG. 1 shows a first embodiment of a photocell, as a particular example of a substrate with stacked deposition layers on opposite substrate surfaces, produced in accordance with the inventive method. The cell comprises a photovoltaic material 100, consisting of a bulk material, such as p-Si, with a thin oppositely doped Si layer at the edge, the emitter 200e. Capping layer 200 has a passivation layer 100e-200ar interface comprising a metal-oxide provided to reduce the Si surface defect densities, an antireflection coating 200ar to enhance the light entrapment and a protective layer 201 consisting of a metal-oxide to protect the cell. The photocell may typically be produced in the following steps, from c-Si material to obtain a passivated emitter and rear cell type.

The substrate is first polished to remove saw damage, textured, and n-type doping applied to produce an emitter layer 100e, e.g. by phosphorous diffusion into the wafer substrate, the excess may be removed by an HF-dip. Alternative an emitter materials may be Boron oxide (BOx). Dependent on the n-type doping step, rear side emitter may be removed by a HF/HNO₃-polishing step. Furthermore, a front side anti reflection coating 200ar and front side- and bulk passivation may be applied by an a-SiNx:H deposition (70-80 nm). A capping layer 201 comprising a metaloxide may be formed on the antireflection coating 200ar. The combination of an anti reflection coating and capping layer may reduce surface recombination velocity substantially, which is vital for enhancing the internal quantum efficiency of the photovoltaic cell.

One example is the capping of SiO₂ with Al₂O₃. This can improve the quality of the SiO₂ passivation layer. By switching from one deposition process (i.e. SiO₂, which can also be deposited by atomic layer deposition (ALD)) to another thus can be beneficial. Al₂O₃ can be used as passivation of both the front and rear of passivated emitter and rear solar cells. The rear may be passivated by an Al₂O₃—SiNₓ:H stack while the front ARC may be passivated by SiNₓ:H capped by Al₂O₃. In addition a stacked layer of Al₂O₃—SiOₓ—SiNₓ:H on the back may enhance the cell efficiency.

The capping layer may be very thin inter alia to enable electron tunneling of the emitter layer, typically in the order of 0.5-3 nm, Al₂O₃, corresponding to 8-25 full ALD cycles, or even below 1 nm, corresponding to 5-10 full ALD cycles. Alternatively, by patterning of the ALD process, metallized contacts may be provided afterwards on designated areas where no AL₂O₃ is deposited.

Alternatively, a capping layer may be provided by depositing (only) Al₂O₃, thus, (without the SiNₓ layer)—and engineer it's thickness to have an optimal antireflection characteristic. Al₂O₃ may be deposited by atomic layer deposition, for instance, so typically, for the front side, 225-1500 cycles may be performed.

Likewise, on the backside, a metal-oxide layer 301 may be applied. The formation of metal-oxide provides a high fixed negative/positive charge density resulting in a field effect passivation that can be especially beneficial for the passivation of the p-type c-Si cell.

The metaloxide may be AL₂O₃, provided by atomic layer deposition. Typically, a layer thickness of 10 nm may be sufficient.

A typical front side stack 200 may be provided by a SiN layer, an SiOₓ layer and an Al₂O₃ capping layer 201. In particular, the front side may be engineered for optimum throughput, by an antireflection layer (typically: SiN).

A typical back side stack 300 may be provided by a stack of Al₂O₃ forming a combination of a field-effect and chemical passivation layer 301, and a possible SiN/SiO₂ layer 302 engineered, with different layer thicknesses, to reflect the light back into the substrate 100. This can be provided by a SiN/SiO₂ passivation stack 302.

It is shown that a stack produced by a first precursor gas can be different in size than a stack produced by the second precursor gas. In particular metal oxides 201 and 301 may have different thicknesses d1, d2, since the interfaces are suited for either sunny-side up or rear side photovoltaic dynamics. The cell may be finished by providing metallized contacts, in particular, by lines 400 which may be screen printed on the front side provided to have metalized front contact; also (full) rear side metallization, for example, by Al screenprinting. A firing step at elevated temperature (800-900° C.) is for passivation of the bulk by hydrogen of the a-SiNₓ:H, for getting the front side metallization 400 through the a-SiNₓ:H and for ‘connection’ of the rear metallization 500 Al with the Si. Finally, edge isolation steps are applied. The rear metallization may be of a full rear side type, for example, an Al layer, or may be provided by a via structure connected to a finger pattern (not shown).

The FIG. 1 embodiment is not limited to a specific photovoltaic cell stack arrangement, but importantly the provision of layers 201 and 301 in stacks 200 and 300 may be manufactured in a single production cycle using spatial atomic layer deposition. In the example, layers 201 and 301 are formed of a metal-oxide, in particular Al₂O₃, and may be formed from first (layer 201) and second (layer 201)precursor gases comprise a metalorganic material, comprising one of aluminum, zink or titanium. First and second precursor gases could be the same precursor gas, in particular, trimethylalumininium. Alternatively, layers 201 and 301 may be of a different composition, provided that the first and second precursor gases are chemically inert relative to each other.

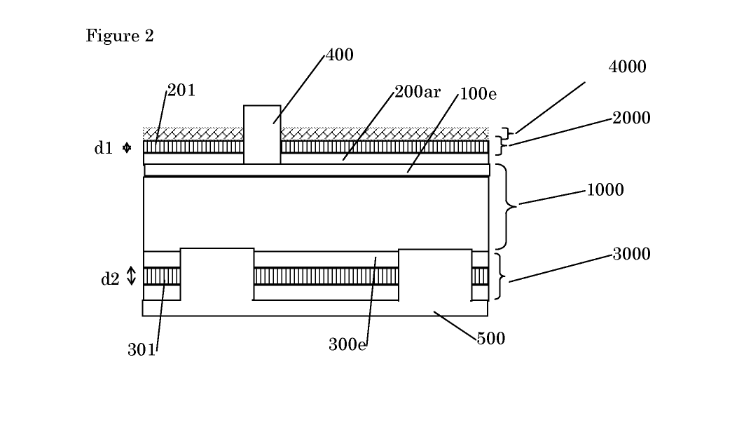

As a further example, FIG. 2 shows another photovoltaic cell, in particular, an n-type phosphoric cell with an Al-back-junction field which is known to reduce the surface recombination velocity. In this arrangement the provision of layers 201 and 301 which may also be manufactured in a single production cycle using spatial atomic layer deposition. According to this embodiment an n-type Si substrate 1000 is polished to remove saw damage, textured, and n+(phosphorous) is doping applied to produced emitter layer 100e, e.g. by phosphorous diffusion into the wafer substrate; the excess may be removed by an HF-dip. A front side anti reflection coating 200ar and front side- and bulk passivation may be applied by a a-SiNₓ:H deposition (70-80 nm), for example by PECVD. The front side stack 2000 may be finished by screen printing Ag lines for front side metallization; this can be put in an oven step for drying the Ag front side metallization.

The back side stack 3000 may be provided with a screen printed Al full rear side for providing a p+doping layer 300e.

The substrate's front and rear sides can be passivated by a passivation layers 201 and 301 respectively, provided by atomic layer deposition of Al₂O₃ that is formed by iteratively performing the steps of respectively contacting opposite sides of substrate 1000 with a first and second precursor gas; and providing at least one of a reactant gas, plasma, laser-generated radiation, and/or ultraviolet radiation for reacting any of the first and second precursor gas after deposition on at least part of the substrate surface. First and second precursor gases are at least in one of the iterations supplied simultaneously, so that an important efficiency can be obtained in manufacturing the photovoltaic cell by simultaneously performing atomic layer deposition on each of opposite sides of the substrate surface.

Thus, a capping layer 201 comprising a metaloxide may be formed on the antireflection coating 200ar and a passivation layer 301 can be formed by contacting opposite substrate surfaces with a first and second precursor gases at least in one of the iterations supplied simultaneously. The thicknesses of layers 201 and 301 may be tailored to the specific photovoltaic constraints of front or rear sides of the substrate 1000. To provide different thicknesses d1 and d2 of the layers 201 and 301 respectively, the supplying of first precursor gas may be stopped at a different time then the supplying of the second precursor gas.

To complete the manufacturing of the photovoltaic cell the rearside of the cell 1000 can be screen printed with Al paste for full rear side metallization, after providing openings in the emitter layer 300e, e.g. by laser cutting. Thus, an Al rear contact 500 can be formed with via structure connected an Al back layer. Subsequently, at high temperature a firing step can be performed, and the edges may be isolated by laser cutting.

Additionally or as an alternative to the provision of a front side contact 400, a transparent conductive oxide (TCO) layer 4000 may be provided. For such a TCO layer for example doped ZnO may be used. Additional TCO materials may be Al doped ZnO (ZnO:AI) or AZO; Gallium doped Zinc oxide ZnO:Ga and Indium doped Tinoxide (SnO2:In).

The TCO layer 4000 can be formed when the same surface is exposed to first and second precursor gasses, which may not be the same. The deposition of the base material, for example ZnO, is done by dosing precursor one and the doping level is controlled by the dose of the second precursor material.

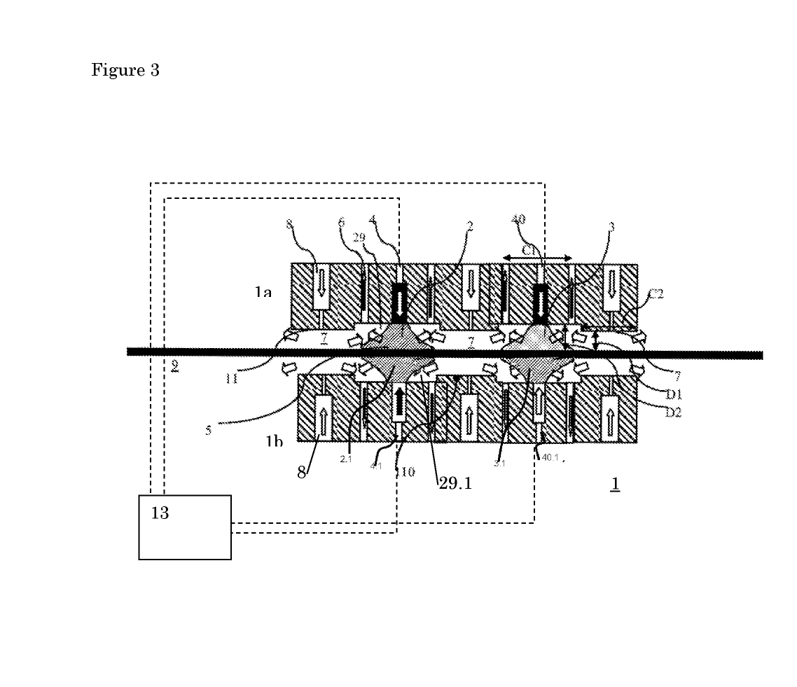

To further illustrate the method of manufacturing the photovoltaic cell, FIG. 3 shows a schematic side view of an apparatus for producing the stacked substrate 2, in particular a substrate 2 having stacked deposition layers on opposite substrate faces, arranged to supply first and second precursor gases at least in one of the iterations simultaneously. Relative motion is established between the printing head 1 and the substrate 2 in the conveying plane, in order to convey the substrate 2 to reactant spaces 3, 3.1 arranged in the injector head device 1 opposite and facing respective sides of the substrate 2. In the printing head device 1, first and second deposition spaces 4 and 4.1 are provided opposite facing each other and in use, facing respective opposite sides of substrate 2. The deposition spaces 4 and 4.1 are arranged to contact the substrate surfaces with respectively a first precursor gas from a first precursor supply and contacting the substrate surfaces with a second precursor gas from a second precursor supply. First and second deposition spaces 4 and 4.1 are in use bounded by the injector head parts 1a and 1b and the substrate surface 2.

In addition, upper part 1a comprises reactant spaces 3 and lower part 1b comprises a correspondingly arranged reactant space 3.1 to contact any of the upper or lower substrate surface with at least one of a reactant gas, a plasma, laser-generated radiation, and ultraviolet radiation, for reacting the precursor after deposition of the precursor gas on at least part of the substrate surface.

The deposition spaces 4 and 3 and 4.1 and 3.1 are separated by a gas bearing region respectively. While for atomic layer in principle, at least two process steps are needed, only one of the process steps may need involvement of material deposition. Such material deposition may be carried out in a deposition space 2 provided with a precursor supply 4. Accordingly, in this embodiment it is shown that injector head 1 comprises a further deposition space 3 provided with a reactant supply 40, the further deposition space 3 in use being bounded by the gas bearing 7. Alternatively or additionally, at least one of a reactant gas, a plasma, laser-generated radiation, and ultraviolet radiation, may be provided in the reaction space for reacting the precursor with the reactant gas after deposition of the precursor gas on at least part of the substrate surface in order to obtain the atomic layer on the at least part of the substrate surface. By suitable purging of spaces 2, 2.1 and 3, 3.1 the supplies 4, 4.1 and 40, 40.1 may be switched during processing. This can be done precisely timed in a manner that the precursor gas only flows into the deposition space while the wafer is present at the position of the deposition space. This will prevent costly precursor gas flowing to the exhaust without use, while the wafer is outside the deposition space, thus further enhancing the precursor gas use efficiency.

Via the user interface of the machine the layer thickness for top and bottom sides of the wafer can be set individually. For example, the wafers could be set for depositing a 3 nm AL₂O₃ layer on the front side of the substrate 2, and a 10 nm on the backside of the substrate 2. For the injector head 2 with a single deposition space, the 10 nm layer could be grown in about 80 iterations. However, after 3 nm (about 25 iterations) the top injector 1a may be shut down. The wafer can be finished to produce the lower layer, and then the new wafer can start with an identical setting or with a setting that is reversed, to minimize the number of switching.

Alternatively, when the number of deposition spaces 4 is higher than one (for example three) some of the deposition spaces may be shut down from active supply with precursor gas; or the number of reactant spaces 3 and 3.1 may be varied, that are supplied with reactant. This could be done by closing a precursor or reactant supply for a designated deposition space. Then, on the top, only one pair of gases would work, and on the bottom, for example, two pair of gases would work. Therefore, the upper and lower parts 1a and 1b could be designed with a number of deposition spaces that differs for first and second precursor gases. This would prevent switching of the gasses, but would render less flexibility in thickness. The upper and lower layer will have a predetermined ratio, for example, a 1:2 or 1:3 ratio, which could render layers of 5 nm:10 nm or 3 nm:9 nm. For a spatial ALD tunnel concept, this could be done by switching off some of the deposition spaces in the upper or lower part 1a or 1b of the print head 1.

Switching of the supply may be controlled by pressure control system 13 arranged to selectively supply any of the first and second precursor supplies of said first and second deposition spaces; and to selectively supply any of the reactant gas, plasma, laser-generated radiation, and/or ultraviolet radiation, in any or both reactant spaces; wherein the pressure control system is further arranged to supply first and second precursor gases at least in one of the iterations simultaneously. The pressure control system is arranged to stop the supplying of first precursor gas at a different time then the supplying of the second precursor gas, in accordance with a set thickness of the ALD layer that is to be deposited on the substrate 2.

The precursor and reactant supplies 4, 4.1, 40, 40.1 are preferably designed without substantial flow restrictions to allow for plasma deposition. Thus, towards a substrate surface 5, plasma flow is unhindered by any flow restrictions.

In this embodiment, a precursor gas is circulated in the deposition space 2 by a flow alongside the substrate surface 5. The gas flow is provided from the precursor supply 4 via the deposition space to the precursor drain 6. In use the deposition space 2 is bounded by the injector head 1 and the substrate surface 5. Gas bearings 7 are provided with a bearing gas injector 8 arranged adjacent the deposition space, for injecting a bearing gas between the injector head 1 and the substrate surface 5, the bearing gas thus forming a gas-bearing while confining the injected precursor gas to the deposition space 2. The precursor drain 6 may additionally function to drain bearing gas preventing flow of bearing gas into the deposition space 2, 3.

While in the embodiment each gas bearing 7 is shown to be dimensioned as a flow barrier, in principle, this is not necessary; for example, a flow barrier separating the deposition spaces 2, 3 need not be dimensioned as a gas bearing as long as an effective flow barrier is provided. Typically, a flow barrier may have a gap height that is larger than a gap height wherein a gas bearing is effective. In practical examples, the gas bearing operates in gap height ranges from 5 um-100 um; wherein a flow barrier may still be effective above such values, for example, until 500 um. Also, gas bearings 7 may only be effective as flow barrier (or gas bearing for that matter) in the presence of substrate 9; while flow barriers may or may not be designed to be active irrespective of the presence of substrate 9. Importantly, flow of active materials between deposition spaces 2, 3 is prevented by flow barriers at any time to avoid contamination. These flow barriers may or may not be designed as gas bearings 7.

While FIG. 3 not specifically shows a conveying system, the substrate 9 is moved relative to the injector head 2, to receive subsequent deposition of materials from deposition spaces 2 and 3. By reciprocating motion of the substrate 9 relative to the injector head 1, the number of layers can be controlled.

Lower part 1b of injector head 1 is provided to provide contactless support for substrate 2 along a conveying plane which may be seen as the centre line of substrate 2. The lower part 1b is arranged opposite the upper part 1a and is constructed to provide a gas bearing pressure arrangement 8 that balances the injector head gas-bearing 7 in the conveying plane. Although less then perfect symmetrical arrangements may be feasible to provide the effect, preferably, the balancing is provided by having an identical flow arrangement in the lower part as is provided by the injector head 1. Thus, preferably, each flow ejecting nozzle of the lower part 1b is symmetrically positioned towards a corresponding nozzle of the injector head 1. The upper and lower part 1a and 1b form a gas bearing pressure arrangement arranged for injecting a bearing gas between the injector head and the substrate surface, so that the substrate is balanced supportless by said gas bearing pressure arrangement in said printing head device.

In this way, the substrate 2 can be held supportless, that is, without a mechanical support, by said gas bearing pressure arrangement in between the injector head 1 and the lower part 1b. More in general, a variation in position, along the conveying plane, of flow arrangements in the injector head 1 and in the lower part 1b, that is smaller than 0.5 mm, in particular smaller than 0.2 mm, may still be regarded as an identical flow arrangement. By absence of any mechanical support, a risk of contamination of such support is prevented which is very effective in securing optimal working height of the injector head 1 relative to the substrate 9. In addition, less down time of the system is necessary for cleaning purposes. Furthermore, importantly, by absence of a mechanical support, a heat capacity of the system can be reduced, resulting in faster heating response of substrates to production temperatures, which may significantly increase production throughput and reduce power consumption.

The deposition spaces 2, 2.1 define deposition space heights D2 relative to a substrate surface; and wherein the gas bearing 7, functioning as flow barrier, comprises a flow restricting surface 11 facing a substrate surface 5, defining, relative to a substrate, a gap distance D1 which is smaller than the deposition space height D2. By suitable design of the gas bearing 7, the support may not suffer from the switched supply of precursor and or reactant gases. In particular, since the distance to the substrate in the gas bearing section is very small, the switching pressures of the process gas are negligible. A typical distance of D1 may range from 5 micrometer to 150 micrometer; a typical distance D2 may range from 20 micrometer to 500 micrometer. A gas bearing pressure will depend on the flow restriction and may be in the order of 50-1000 mBar. The deposition spaces 2 and 2.1 are provided with respective first precursor supply 4 and second precursor gas supply 4.1, and a precursor drain 6. Said supply and drain may be arranged for providing a precursor gas flow from the precursor supply via the deposition space to the precursor drain. In use, the deposition space is bounded by the injector head 1 and the substrate surface. The deposition space 2 and 2.1 may be formed by cavities 29 and 29.1 that are symmetric relative to the conveying plane and have a depth D2-D1, in which the supply and drain end and/or begin. Thus, more in general, the cavity is defined in the deposition head 1 and is, in use, facing the substrate 9. By having the cavity 29 facing the substrate, it is understood that the substrate is substantially forming a closure for the cavity, so that a closed environment is formed for supplying the precursor gas. In addition, the substrate may be provided such that various adjacent parts of the substrate or even adjacent substrates or other parts may be forming such closure. The apparatus may be arranged for draining the precursor gas by means of the precursor drain 6 of the deposition head 1 from the cavity for substantially preventing precursor gas to escape from the cavity. It may be clear that the bearing supply may be positioned at a distance from the cavity. The cavity may enable to apply process conditions in the cavity that are different from process conditions in the gas-bearing layer. Preferably, the precursor supplies 4 and 4.1 and/or the precursor drain 6 are positioned in the cavities 29 and 29.1 respectively.

The depth D2-D1 of the cavities 29 and 29.1 may be defined as a local increase in distance between the substrate 9 and an output face of the injector head provided with the bearing gas injector 8 and the precursor supply. The depth D2 minus D1 may be in a range from 10 to 500 micrometers, more preferably in a range from 10 to 100 micrometers.

The flow restricting surface 11 may be formed by projecting portions 110 including bearing gas injector 8. The gas-bearing layer in use is for example formed between the surface 5 and the flow restricting surface 11. A distance C1 between the precursor drains 30 may typically be in a range from 1 to 10 millimeter, which is also a typical width of the deposition space 2, 3. A typical thickness of the gas-bearing layer, indicated by D1, may be in a range from 3 to 15 micrometer. To accommodate for various surface flatness qualities, however, the bearing gap may larger than 15 micrometer, for example, extended to larger dimensions, for example, up to 70 micrometer. A typical width C2 of the projecting portion 110 may be in a range from 1 to 30 millimeter. A typical thickness D2 of the deposition space 2 out of the plane of the substrate 9 may be in a range from 3 to 300 micrometer.

This enables more efficient process settings. As a result, for example, a volumetric precursor flow rate injected from any of supplies 4 and 4.1 into the deposition space 2 can be higher than a volumetric flow rate of the bearing gas in the gas-bearing layer, while a pressure needed for the injecting of the precursor gas can be smaller than a pressure needed for injecting the bearing gas in the gas-bearing layer. It will thus be appreciated that the thickness D₁ of the gas-bearing layer 7 may in general be less than a thickness D₂ of the deposition space 2, measured in a plane out of the substrate surface.

At a typical flow rate of 5·10⁻⁴-2·10⁻³ m³/s per meter channel width and a typical distance of L=5 mm, e.g. being equal to a distance from the precursor supply to the precursor drain, the channel thickness D_{c}, e.g. the thickness D₂ of the deposition space 2, should preferably be larger than 25-40 μm. However, the gas-bearing functionality preferably requires much smaller distances from the precursor injector head to the substrate, typically of the order of 5 μm, in order to meet the important demands with respect to stiffness and gas separation and in order to minimize the amount of bearing gas required. The thickness D₂ in the deposition space 2 being 5 μm however, with the above-mentioned process conditions, may lead to unacceptably high pressure drops of ˜20 bar. Thus, a design of the apparatus with different thicknesses for the gas-bearing layer (i.e. the thickness D₁) and deposition space (i.e. the thickness D₂) is preferably required. For flat substrates, e.g. wafers—or wafers containing large amounts of low aspect ratio (i.e. shallow) trenches 8 having an aspect ratio A (trench depth divided by trench width)≦10−the process speed depends on the precursor flow rate (in kg/s): the higher the precursor flow rate, the shorter the saturation time.

For wafers containing large amounts of high aspect ratio (i.e. deep narrow) trenches of A≧50, the process speed may depend on the precursor flow rate and on the precursor partial pressure. In both cases, the process speed may be substantially independent of the total pressure in the deposition space 2. Although the process speed may be (almost) independent of total pressure in the deposition space 2, a total pressure in the deposition space 2 close to atmospheric pressure may be beneficial for several reasons:
1. At sub-atmospheric pressures, the gas velocity v_{g} in the deposition space 2 is desired to increase, resulting in an undesirably high pressure drop along the deposition space 2.
2. At lower pressures, the increase in the gas velocity v_{g} leads to a shorter gas residence time in the deposition space 2, which has a negative effect on yield.
3. At lower pressures, suppression of precursor leakage from the deposition space 2 through the gas-bearing layer may be less effective.
4. At lower pressures, expensive vacuum pumps may be required.

The lower limit of the gas velocity v_{g} in the deposition space 2 may be determined by the substrate traverse speed vₛ: in general, in order to prevent asymmetrical flow behaviour in the deposition space 2, the following condition should preferably be satisfied:

V_{g}>>Vₛ

This condition provides a preferred upper limit of the thickness D, D₂ of the reaction space 3. By meeting at least one, and preferably all, of the requirements mentioned above, an ALD deposition system is obtained for fast continuous ALD on flat wafers and for wafers containing large amounts of high aspect ratio trenches.

Accordingly, in use, the total gas pressure in the deposition space 2 may be different from a total gas pressure in the additional deposition space 3. The total gas pressure in the deposition space 2 and/or the total gas pressure in the additional deposition space 3 may be in a range from 0.2 to 3 bar, for example 0.5 bar or 2 bar or even as low as 10 mBar, in particular, in a range of 0.01 bar to 3 bar. Such pressure values may be chosen based on properties of the precursor, for example a volatility of the precursor. In addition, the apparatus may be arranged for balancing the bearing gas pressure and the total gas pressure in the deposition space, in order to minimize flow of precursor gas out of the deposition space.

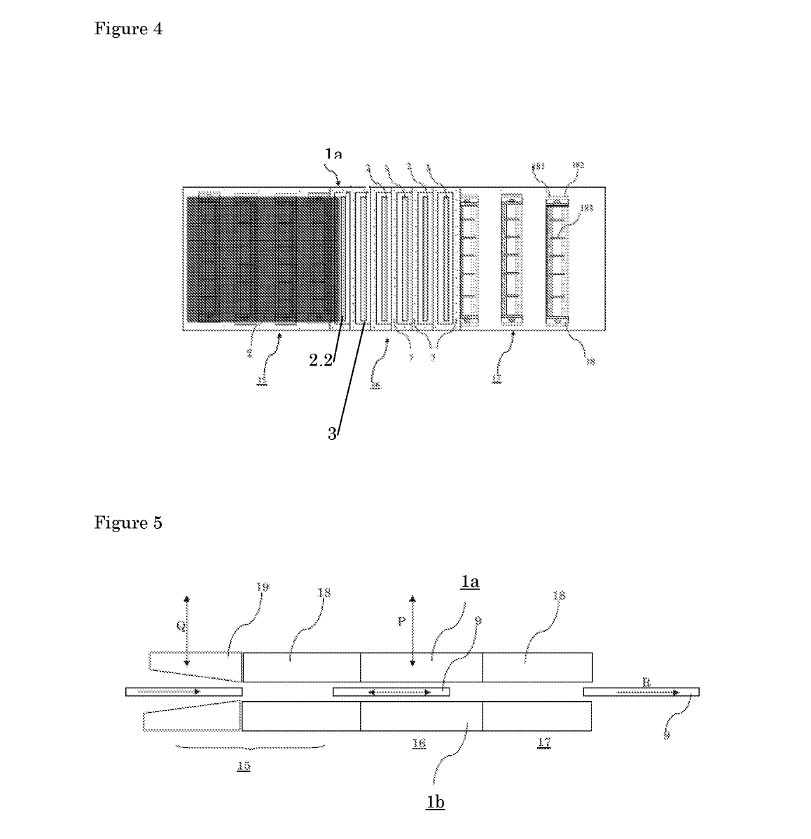

FIG. 4 shows a schematic plan view of another embodiment. Here only an upper part 1a of the injector head 1 is schematically depicted in plan view. The injector head 1a comprises alternating slits of deposition spaces 2, 3, for precursors and reactants respectively, each bounded by gas bearings/flow barriers 7.

In an further embodiment, the injector head 1 is adapted to supply a third precursor gas in a deposition space 2.2, different from first and second precursor gases, from a third precursor supply in a third deposition space arranged in any of the injector head device and separated from the first or second deposition space by a confining gas curtain to provide a doped stacked layer.

The use of doped layers can be beneficial for a number of applications, such as Transparent conductive oxides (TCO's) photodetectors and LED's. Besides these uses, doped layers can also be used for surface passivation by Al₂O₃. The use of for example ZnO (which can be deposited with ALD) as a base material is useful when it is doped with another metal. The use of TCO's and Ti doped Al₂O₃ are especially beneficial for high efficiency solar cells. TCO can be used as front side contacts as a replacement of the metal contacts to circumvent shading, and Al₂O₃—TiO₂ pseudobinary alloys are known to passivate p-type Si surfaces. This doped material can be deposited in-line and with a wider doping concentration level as with for example CVD resulting in a high control in the stoichiometry and thus the properties of these layers. Alternatively, the precursor flow for a single deposition space 2 may be switched controllably between the 2 precursors so that controllable doping level can be achieved.

The substrate is seen to be carried into working zone 16 where injector head 1 is active, from a lead in zone 15. The working zone 16 is adjacent the lead in zone 15 and is aligned relative to the conveying plane, so that the substrate can be easily conveyed between these zones 15, 16. An additional lead out zone 17 may be provided. Depending on process steps, lead in and lead out can be interchanged or alternated. Thus, a substrate 9 can be moved reciprocatingly along a center line between the two zones 15, 17 through working zone 16.

In the shown embodiment the conveying system is provided with pairs of gas inlets 181 and outlets 182 facing the conveying plane and providing a flow 183 along the conveying plane from the outlet 182 towards the inlet 181. For clarity reasons only one pair is referenced in the figure. A gas flow control system is arranged to provide a gas bearing pressure and a gas flow 183 along the conveying plane, to provide movement of the substrate 9 along the conveying plane along a center line through the working zone 16 by controlling the gas flow.

FIG. 5 shows a schematic side view of a another embodiment. Reference is made to the previous figures. In particular, a lead in zone 15 is shown, a working zone 16 and a lead out zone 17. The working zone is formed by injector head device 1, head parts 1a and 1b. In the lead in and lead out zone, transport elements or drive sections 18 are provided for providing a transport of the substrate 9 along a conveying plane, indicated by direction R. According to an embodiment, the lead in zone 15 comprises slanted wall parts 19 facing the conveying plane. The drive section 18 comprises transport elements (not shown) arranged to provide relative movement of the substrate and the injector head along a plane of the substrate to form a conveying plane along which the substrate is conveyed. The lead in zone 15 comprises slanted wall parts symmetrically arranged relative to the conveying plane coinciding with substrate 9. The slanted wall parts 19 are formed and constructed to reduce a working height Dx from about 100-200 micron above the substrate 9 in a first conveying direction P towards the drive section 18 to a reduced working height of ranging from 30-100 micron, preferably about 50 micron, forming the smallest gap distance Dy.

The movement in the plane out of the substrate surface may help confining the injected precursor gas. The gas-bearing layer allows the injector head to approach the substrate surface and/or the substrate holder closely, for example within 50 micrometer or within 15 micrometer, for example in a range from 3 to 10 micrometer, for example 5 micrometer. Such a close approach of the injector head to the substrate surface and/or the substrate holder enables confinement of the precursor gas to the deposition space, as escape of the precursor gas out of the deposition space is difficult because of the close approach. The substrate surface in use bounding the deposition space may enable the close approach of the injector head to the substrate surface. Preferably, the substrate surface, in use, is free of mechanical contact with the injector head. Such contact could easily damage the substrate.

Optionally, the precursor supply forms the gas injector. However, in an embodiment, the gas injector is formed by a bearing-gas injector for creating the gas-bearing layer, the bearing-gas injector being separate from the precursor supply. Having such a separate injector for the bearing gas enables control of a pressure in the gas-bearing layer separate from other gas pressures, for example the precursor gas pressure in the deposition space. For example, in use the precursor gas pressure can be lower than the pressure in the gas-bearing layer. Optionally, the precursor gas pressure is below atmospheric pressure, for example in a range from 0.01 to 100 millibar, optionally in a range from 0.1 to 1 millibar. Numerical simulations performed by the inventors show that in the latter range, a fast deposition process may be obtained. A deposition time may typically be 10 microseconds for flat substrates and 20 milliseconds for trenched substrates, for example when chemical kinetics are relatively fast. The total gas pressure in the deposition space may typically be 10 millibar. The precursor gas pressure may be chosen based on properties of the precursor, for example a volatility of the precursor. The precursor gas pressure being below atmospheric pressure, especially in the range from 0.01 to 100 millibar, enables use of a wide range of precursors, especially precursors with a wide range of volatilities.

The gas-bearing layer in use typically shows a strong increase of the pressure in the gas-bearing layer as a result of the close approach of the injector head towards the substrate surface. For example, in use the pressure in the gas-bearing layer at least doubles, for example typically increases eight times, when the injector head moves two times closer to the substrate, for example from a position of 50 micrometer from the substrate surface to a position of 25 micrometer from the substrate surface, ceteris paribus. Preferably, a stiffness of the gas-bearing layer in use is between 10³ and 10¹⁰ Newton per meter, but can also be outside this range. Such elevated gas pressures may for example be in a range from 1.2 to 20 bar, in particular in a range from 3 to 8 bar. A stronger flow barrier in general leads to higher elevated pressures. An elevated precursor gas pressure increases a deposition speed of the precursor gas on the substrate surface. As deposition of the precursor gas often forms an important speed-limiting process step of atomic layer deposition, this embodiment allows increasing of the speed of atomic layer deposition. Speed of the process is important, for example in case the apparatus is used for building a structure that includes a plurality of atomic layers, which can occur often in practice. Increasing of the speed increases a maximum layer thickness of a structure that can be applied by atomic layer deposition in a cost-effective way, for example from 10 nanometer to values above 10 nanometer, for example in a range from 20 to 50 nanometer or even typically 1000 nanometer or more, which can be realistically feasible in several minutes or even seconds, depending on the number of process cycles. As non limiting indication, a production speed may be provided in the order of several nm/second. The apparatus will thus enable new applications of atomic layer deposition such as providing barrier layers in foil systems. One example can be a gas barrier layer for an organic led that is supported on a substrate. Thus, an organic led, which is known to be very sensitive to oxygen and water, may be manufactured by providing an ALD produced barrier layer according to the disclose method and system. Typical barrier layers that may be produced include Silicon oxide SiOx, Titanium oxide TiOx, Aluminum oxide AlOx; Silicon nitride SiNx; Silicon carbide SiCx; Amorphous Silicon a-Si and Titanium nitride TiN layers. Such layers may have a number of functions: passivation; (anti) reflection or barrier against diffusion, e.g against Copper diffusion in Silicon.

In an embodiment, the apparatus is arranged for applying a prestressing force on the injector head directed towards the substrate surface along direction P. The gas injector may be arranged for counteracting the prestressing force by controlling the pressure in the gas-bearing layer. In use, the prestressing force increases a stiffness of the gas-bearing layer. Such an increased stiffness reduces unwanted movement out of the plane of the substrate surface. As a result, the injector head can be operated more closely to the substrate surface, without touching the substrate surface.

Alternatively or additionally, the prestressing force may be formed magnetically, and/or gravitationally by adding a weight to the injector head for creating the prestressing force. Alternatively or additionally, the prestressing force may be formed by a spring or another elastic element.

In an embodiment, the precursor supply is arranged for flow of the precursor gas in a direction transverse to a longitudinal direction of the deposition space. In an embodiment, the precursor supply is formed by at least one precursor supply slit, wherein the longitudinal direction of the deposition space is directed along the at least one precursor supply slit. Preferably, the injector head is arranged for flow of the precursor gas in a direction transverse to a longitudinal direction of the at least one precursor supply slit. This enables a concentration of the precursor gas to be substantially constant along the supply slit, as no concentration gradient can be established as a result of adhesion of the precursor gas to the substrate surface. The concentration of the precursor gas is preferably chosen slightly above a minimum concentration needed for atomic layer deposition. This adds to efficient use of the precursor gas. Preferably, the relative motion between the deposition space and the substrate in the plane of the substrate surface, is transverse to the longitudinal direction of the at least one precursor supply slit. Accordingly, the precursor drain is provided adjacent the precursor supply, to define a precursor gas flow that is aligned with a conveying direction of the substrate.

In an embodiment, the gas-bearing layer forms the confining structure, in particular the flow barrier. In this embodiment, an outer flow path may at least partly lead through the gas-bearing layer. As the gas-bearing layer forms a rather effective version of the confining structure and/or the flow barrier, loss of the precursor gas via the outer flow path may be prevented.

In an embodiment, the flow barrier is formed by a confining gas curtain and/or a confining gas pressure in the outer flow path. These form reliable and versatile options for forming the flow barrier. Gas that forms the confining gas curtain and/or pressure may as well form at least part of the gas-bearing layer. Alternatively or additionally, the flow barrier is formed by a fluidic structure that is attached to the injector head. Preferably, such a fluidic structure is made of a fluid that can sustain temperatures up to one of 80° C., 200° C., 400° C., and 600° C. Such fluids as such are known to the skilled person.

In an embodiment, the flow barrier is formed by a flow gap between the injector head and the substrate surface and/or between the injector head and a surface that extends from the substrate surface in the plane of the substrate surface, wherein a thickness and length of the flow gap along the outer flow path are adapted for substantially impeding the volumetric flow rate of the precursor gas along the outer flow path compared to the volumetric flow rate of the injected precursor gas. Preferably, such a flow gap at the same time forms, at least part of, the outer flow path. Preferably, a thickness of the flow gap is determined by the gas-bearing layer. Although in this embodiment a small amount of the precursor gas may flow out of the deposition space along the outer flow path, it enables a rather uncomplicated yet effective option for forming the flow barrier.

In an embodiment, the deposition space has an elongated shape in the plane of the substrate surface. A dimension of the deposition space transverse to the substrate surface may be significantly, for example at least 5 times or at least 50 times, smaller than one or more dimensions of the deposition space in the plane of the substrate surface. The elongated shape can be planar or curved. Such an elongated shape diminishes a volume of the precursor gas that needs to be injected in the deposition space, thus enhancing the efficiency of the injected gas. It also enables a shorter time for filling and emptying the deposition space, thus increasing the speed of the overall atomic layer deposition process.

In an embodiment, the deposition space of the apparatus is formed by a deposition gap between the substrate surface and the injector head, preferably having a minimum thickness smaller than 50 micrometer, more preferably smaller than 15 micrometer, for example around 3 micrometer. The flow gap may have similar dimensions. A deposition space having a minimum thickness smaller than 50 micrometer enables a rather narrow gap leading to a rather efficient use of the precursor gas, while at the same time avoiding imposing stringent conditions on deviations in a plane out of the substrate surface of the positioning system that establishes the relative motion between the deposition space and the substrate in the plane of the substrate surface. In this way the positioning system can be less costly. A minimum thickness of the deposition gap smaller than 15 micrometer may further enhance efficient use of the precursor gas.

The gas-bearing layer enables the flow gap and/or the deposition gap to be relatively small, for example having its minimum thickness smaller than 50 micrometer or smaller than 15 micrometer, for example around 10 micrometer, or even close to 3 micrometer.

In an embodiment, the injector head further comprises a precursor drain and is arranged for injecting the precursor gas from the precursor supply via the deposition space to the precursor drain. The presence of the precursor drain offers the possibility of continuous flow through the deposition space. In continuous flow, high-speed valves for regulating flow of the precursor gas may be omitted. Preferably, a distance from the precursor drain to the precursor supply is fixed during use of the apparatus. Preferably, in use the precursor drain and the precursor supply are both facing the substrate surface. The precursor drain and/or the precursor supply may be formed by respectively a precursor drain opening and/or a precursor supply opening.

In an embodiment, the precursor drain is formed by at least one precursor drain slit. The at least one precursor drain slit and/or the at least one precursor supply slit may comprise a plurality of openings, or may comprise at least one slot. Using slits enables efficient atomic layer deposition on a relatively large substrate surface, or simultaneous atomic layer deposition on a plurality of substrates, thus increasing productivity of the apparatus. Preferably, a distance from the at least one precursor drain slit to the at least one precursor supply slit is significantly smaller, for example more than five times smaller, than a length of the precursor supply slit and/or the precursor drain slit. This helps the concentration of the precursor gas to be substantially constant along the deposition space.

In an embodiment, the apparatus is arranged for relative motion between the deposition space and the substrate in the plane of the substrate surface, by including a reel-to-reel system arranged for moving the substrate in the plane of the substrate surface. This embodiment does justice to a general advantage of the apparatus, being that a closed housing around the injector head for creating vacuum therein, and optionally also a load lock for entering the substrate into the closed housing without breaking the vacuum therein, may be omitted. The reel-to-reel system preferably forms the positioning system.

According to an aspect, the invention provides a linear system wherein the substrate carrier is conveniently provided by air bearings. This provides an easy and predictable substrate movement which can be scaled and continuously operated.

The precursor gas can for example contain Hafnium Chloride (HfCl4), but can also contain another type of precursor material, for example Tetrakis-(Ethyl-Methyl-Amino) Hafnium or TMA-Trimethylaluminium (Al(CH₃)₃). Other precursor gases can be DiEthylZink (DEZ); H2O; Silaan (SiCl4); Ozon (O3) and Tetraetoxysilane (TEOS). The precursor gas can be injected together with a carrier gas, such as nitrogen gas or argon gas. A concentration of the precursor gas in the carrier gas may typically be in a range from 0.01 to 1 volume %. In use, a precursor gas pressure in the deposition space 2 may typically be in a range from 0.1 to 1 millibar, but can also be near atmospheric pressure, or even be significantly above atmospheric pressure. The injector head may be provided with a heater for establishing an elevated temperature in the deposition space 2, for example in a range between 130 and 330° C.

In use, a typical value of the volumetric flow rate of the precursor gas along the outer flow path may be in a range from 500 to 3000 sccm (standard cubic centimeters per minute).

In general, the apparatus may be arranged for providing at least one of a reactant gas, a plasma, laser-generated radiation, and ultraviolet radiation, in a reaction space for reacting the precursor after deposition of the precursor gas on at least part of the substrate surface 4. In this way for example plasma-enhanced atomic laser deposition may be enabled, which may be favourable for processing at low temperatures, typically lower than 130° C. to facilitate ALD processes on plastics, for example, for applications of flexible electronics such as OLEDs on flexible foils etc, or processing of any other materials sensitive to higher temperatures (typically, higher than 130°). Plasma-enhanced atomic layer deposition is for example suitable for deposition of low-k Aluminum Oxide (Al₂O₃) layers of high quality, for example for manufacturing semiconductor products such as chips and solar cells. The reactant gas contains for example an oxidizer gas such as Oxygen (O₂), ozone (O₃), and/or water (H₂O).

In an example of a process of atomic layer deposition, various stages can be identified. In a first stage, the substrate surface is exposed to the precursor gas, for example Hafnium Tetra Chloride. Deposition of the precursor gas is usually stopped if the substrate surface 4 is fully occupied by precursor gas molecules. In a second stage, the deposition space 2 is purged using a purge gas, and/or by exhausting the deposition space 2 by using vacuum. In this way, excess precursor molecules can be removed. The purge gas is preferably inert with respect to the precursor gas. In a third stage, the precursor molecules are exposed to the reactant gas, for example an oxidant, for example water vapour (H₂O). By reaction of the reactant with the deposited precursor molecules, the atomic layer is formed, for example Hafnium Oxide (HfO₂). This material can be used as gate oxide in a new generation of transistors. In a fourth stage, the reaction space is purged in order to remove excess reactant molecules.

Although it may not be explicitly indicated, any apparatus according one embodiment may have features of the apparatus in another embodiment.

The invention is not limited to any embodiment herein described and, within the purview of the skilled person, modifications are possible which may be considered within the scope of the appended claims. For example, the invention also relates to a plurality of apparatuses and methods for atomic layer deposition using a plurality of apparatuses.

Equally all kinematic inversions are considered inherently disclosed and to be within the scope of the present invention. The use of expressions like: “preferably”, “in particular”, “typically”, etc. is not intended to limit the invention. The indefinite article “a” or “an” does not exclude a plurality. For example, an apparatus in an embodiment according to the invention may be provided with a plurality of the injector heads. It may further be clear that the terms ‘relative motion’ and ‘relative movement’ are used interchangeably. Aspects of disclosed embodiment may be suitably combined with other embodiments and are deemed disclosed. Features which are not specifically or explicitly described or claimed may be additionally included in the structure according to the present invention without deviating from its scope.

1. A method for producing a substrate with stacked deposition layers, comprising:
a) providing an injector head device comprising a gas bearing pressure arrangement;
b) injecting bearing gas from the gas bearing pressure arrangement against opposite substrate surfaces, to balance the substrate supportless in a conveying plane in the injector head device; and iteratively performing
c) contacting opposite substrate surfaces with a first precursor gas from a first precursor supply; and with a second precursor gas from a second precursor supply respectively, first and second precursor gases supplied in first and second deposition spaces arranged opposite and facing respective sides of the substrate;
d) establishing relative motion between the deposition space and the substrate in the conveying plane, in order to convey the substrate to reactant spaces arranged in the injector head device opposite and facing respective sides of the substrate; and
e) providing at least one of a reactant gas, plasma, laser-generated radiation, and/or ultraviolet radiation, in any or both reactant spaces for reacting any of the first and second precursor gas after deposition on at least part of the substrate surface in order to obtain an atomic layer on each of opposite sides of the substrate surface;
f) wherein first and second precursor gases are at least in one of the iterations supplied simultaneously on opposite substrate surfaces.

2. The method for producing a stacked substrate according to claim 1, wherein the supplying of first precursor gas is stopped at a different time then the supplying of the second precursor gas.

3. The method for producing a stacked substrate according to claim 1, wherein a number of deposition spaces differs for first and second precursor gases.

4. The method for producing a stacked substrate according to claim 1, wherein the first and second precursor gases are chemically inert relative to each other.

5. The method for producing a stacked substrate according to claim 1, wherein the first and second precursor gases comprise a metalorganic material, comprising one of aluminum, zink or titanium.

6. The method for producing a stacked substrate according to claim 1, wherein further comprising a step of supplying a third precursor gas, different from first and second precursor gases, from a third precursor supply in a third deposition space arranged in any of the injector head device and separated from the first or second deposition space by a confining gas curtain to provide a doped stacklayer.

7. The method for producing a stacked substrate according to claim 1, wherein a stack produced by the first precursor gas is different in size then the stack produced by the second precursor gas.

8. An apparatus for producing a substrate with stacked deposition layers, comprising:
an injector head device comprising
first and second deposition spaces connected to first and second precursor gas supplies, in use, arranged opposite and facing respective opposite sides of a substrate and arranged to contact the substrate surfaces with a first precursor gas from the first precursor supply; and contacting the substrate surfaces with a second precursor gas from the second precursor supply; the first and second deposition spaces in use being bounded by the injector head and the substrate surface;
first and second reactant spaces, oppositely arranged and in use, facing respective opposite sides of a substrate and arranged to contact any of the substrate surfaces with at least one of a reactant gas, a plasma, laser-generated radiation, and ultraviolet radiation, for reacting the precursor after deposition of the precursor gas on at least part of the substrate surface; the first and second reactant spaces in use being bounded by the substrate surface; and
a gas bearing pressure arrangement arranged for injecting a bearing gas between the injector head and the substrate surface, so that the substrate is balanced supportless by said gas bearing pressure arrangement in said printing head device;
a pressure control system arranged to selectively supply any of the first and second precursor supplies of said first and second deposition spaces; and to selectively supply any of the reactant gas, plasma, laser-generated radiation, and/or ultraviolet radiation, in any or both reactant spaces; wherein the pressure control system is further arranged to supply first and second precursor gases at least in one of the iterations simultaneously on opposite substrate surfaces; and
a conveying system arranged to provide relative movement of the substrate and the injector head along a plane of the substrate to form a conveying plane along which the substrate is conveyed between first and second deposition spaces and first and second reactant spaces.

9. The apparatus according to claim 7, wherein the pressure control system is arranged to stop the supplying of first precursor gas at a different time then the supplying of the second precursor gas.

10. The apparatus according to claim 7, wherein a number of deposition spaces differs for first and second precursor gases.
